(19) United States
(12) Patent Application Publication
(10) Pub. No.: US 2024/0105628 A1
(43) Pub. Date: Mar. 28, 2024

(54) RADIO FREQUENCY MODULE AND COMMUNICATION APPARATUS

(71) Applicant: Murata Manufacturing Co., Ltd., Kyoto (JP)

(72) Inventors: Hiromichi KITAJIMA, Kyoto (JP); Takanori UEJIMA, Kyoto (JP); Naoya MATSUMOTO, Kyoto (JP)

(21) Appl. No.: 18/496,304

(22) Filed: Oct. 27, 2023

Related U.S. Application Data
(63) Continuation of application No. PCT/JP2022/022845, filed on Jun. 6, 2022.

(30) Foreign Application Priority Data
Jun. 7, 2021 (JP) 2021-095486

(51) Int. Cl. H01L 23/538; H01L 23/31; H01L 23/498; H01L 23/552; H01L 25/16

(52) U.S. Cl. CPC H01L 23/5383; H01L 23/3121; H01L 23/49811; H01L 23/5385; H01L 23/5386; H01L 23/552; H01L 25/16; H01L 24/16; H01L 2224/16225

(57) ABSTRACT

A radio frequency module includes a mounting substrate, a first electronic component, a second electronic component, a connection terminal, and a wiring layer. The second electronic component is disposed on the second main surface of the mounting substrate. The connection terminal is disposed on the second main surface of the mounting substrate and is connected to the mounting substrate and the wiring layer. The wiring layer faces the second main surface of the mounting substrate with the second electronic component interposed therebetween and is in contact with the connection terminal. The wiring layer has a base material and an external connection electrode. The base material has a second conductive member connected to the first conductive member of the mounting substrate with the connection terminal interposed therebetween. The external connection electrode is connected to the second conductive member. The wiring layer is in contact with the second electronic component.

### CROSS REFERENCE TO RELATED APPLICATION

This is a continuation of International Application No. PCT/JP2022/022845 filed on Jun. 6, 2022 which claims priority from Japanese Patent Application No. 2021-095486 filed on Jun. 7, 2021. The contents of these applications are incorporated herein by reference in their entireties.

### BACKGROUND ART

### Technical Field

The present disclosure typically relates to a radio frequency module and a communication apparatus, and in more detail, relates to a radio frequency module including a mounting substrate, a plurality of electronic components, and a plurality of connection terminals and a communication apparatus including the radio frequency module.

Patent Document 1 describes a radio frequency module. The radio frequency module described in Patent Document 1 includes a module substrate (mounting substrate), a semiconductor IC (second electronic component), a plurality of columnar electrodes (plurality of connection terminals), filters, and an inductor (first electronic component). The module substrate has a first main surface and a second main surface that are opposite to each other. The filters and the inductor is disposed on the first main surface of the module substrate. The semiconductor IC and the plurality of columnar electrodes are disposed on the second main surface of the module substrate.

Patent Document 1: International Publication No. 2020/071021

### BRIEF SUMMARY

In the radio frequency module in the related art described in Patent Document 1, the second electronic component is mounted on the second main surface of the mounting substrate. Accordingly, it is not possible to dispose the columnar electrodes serving as externally connected terminals in the area in which the second electronic component is mounted and that is included in the second main surface of the mounting substrate, and the degree of freedom in designing the externally connected terminals (external connection electrodes) is limited.

In addition, in the technical field of a radio frequency module, there is a demand for height reduction in the radio frequency module.

The present disclosure provides a radio frequency module and a communication apparatus for which a higher degree of freedom in designing an externally connected terminal and height reduction can be achieved.

A radio frequency module according to an aspect of the present disclosure includes a mounting substrate, a first electronic component, a second electronic component, a plurality of connection terminals, and a wiring layer. The mounting substrate has a first main surface and a second main surface that are opposite to each other. The first electronic component is disposed on the first main surface of the mounting substrate. The second electronic component is disposed on the second main surface of the mounting substrate. The plurality of connection terminals are disposed on the second main surface of the mounting substrate and are connected to the mounting substrate. The wiring layer faces the second main surface of the mounting substrate with the second electronic component interposed therebetween and is in contact with the plurality of connection terminals. The second electronic component is located between the mounting substrate and the wiring layer. The wiring layer has a base material and a plurality of external connection electrodes. The base material has a third main surface and a fourth main surface that are opposite to each other and is connected to the plurality of connection terminals with the third main surface interposed therebetween. The plurality of external connection electrodes are disposed on the fourth main surface of the base material. The mounting substrate has a first conductive member connected to the second electronic component. The base material has a second conductive member connected to the first conductive member with at least one of the plurality of connection terminals interposed therebetween. At least one of the plurality of external connection electrodes is connected to the second conductive member. The wiring layer is in contact with the second electronic component.

A communication apparatus according to an aspect of the present disclosure includes the radio frequency module and a signal processing circuit. the signal processing circuit processes a signal that passes through the radio frequency module.

According to the radio frequency module and the communication apparatus according to the aforementioned aspect of the present disclosure, a higher degree of freedom in designing an externally connected terminal and height reduction can be achieved.

### BRIEF DESCRIPTION OF THE DRAWINGS

FIG. 1 is a cross-sectional view of a radio frequency module according to an embodiment.

FIG. 2 is a plan view of the radio frequency module above.

FIG. 3 is a lower surface view of the radio frequency module above.

FIG. 4 is a schematic view of a communication apparatus according to the embodiment.

FIG. 5 is a cross-sectional view of a radio frequency module according to Modification 1.

FIG. 6 is a cross-sectional view of a radio frequency module according to Modification 2.

FIG. 7 is a cross-sectional view of a radio frequency module according to Modification 4.

FIG. 8 is a cross-sectional view of a radio frequency module according to Modification 5.

FIG. 9 is a cross-sectional view of a radio frequency module according to Modification 6.

FIG. 10 is a cross-sectional view of a radio frequency module according to Modification 7.

### DETAILED DESCRIPTION

Hereinafter, a radio frequency module and a communication apparatus according to an embodiment will be described with reference to the drawings. Each drawing referred to in the embodiment and the like is a schematic view, and a ratio in each of the size and the thickness of each of components in the drawing does not necessarily reflect the actual scale ratio.

### Embodiment

### (1) Radio Frequency Module

The configuration of a radio frequency module 1 according to this embodiment will be described with reference to the drawings.

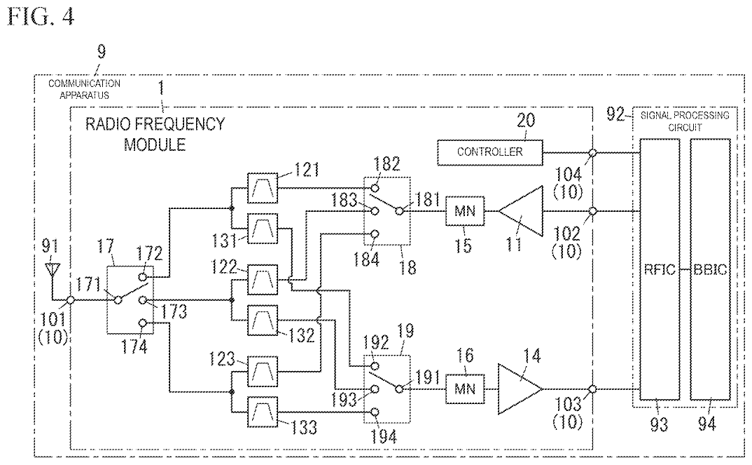

As illustrated in FIG. 4, the radio frequency module 1 is used for, for example, a communication apparatus 9. The communication apparatus 9 is a mobile phone such as a smartphone. The communication apparatus 9 is not limited to a mobile phone and may be a wearable terminal such as a smart watch. The radio frequency module 1 is a module conformable to a 4G (fourth-generation mobile communication) standard, a 5G (fifth-generation mobile communication) standard, or the like. The 4G standard is, for example, a 3GPP (Third Generation Partnership Project, registered trademark) or LTE (Long Term Evolution, registered trademark) standard. The 5G standard is, for example, 5G new radio (NR). The radio frequency module 1 is a module that can support, for example, carrier aggregation and dual connectivity.

The communication apparatus 9 performs communication in a plurality of communication bands. In more detail, the communication apparatus 9 transmits transmission signals in the plurality of communication bands and receives reception signals in the plurality of communication bands.

Part of the transmission signals and the reception signals in the plurality of communication bands is a frequency division duplex (FDD) signal. Each of the transmission signals and the reception signals in the plurality of communication bands is not limited to the FDD signal and may be a time division duplex (TDD) signal. FDD is wireless communication technology by which respective different frequency bands are assigned to transmission and reception in the wireless communications to perform the transmission and the reception. TDD is wireless communication technology in which the same frequency band is assigned to transmission and reception in the wireless communications to perform the transmission and the reception.

### (2) Circuit Configuration of Radio Frequency Module

Hereinafter, the circuit configuration of the radio frequency module 1 according to this embodiment will be described with reference to FIG. 4.

As illustrated in FIG. 4, the radio frequency module 1 according to this embodiment includes a power amplifier 11, a plurality of (illustrated example, three) transmission filters 121 to 123, a plurality of (illustrated example, three) reception filters 131 to 133, a low noise amplifier 14, an output matching circuit 15, an input matching circuit 16, a first switch 17, a second switch 18, a third switch 19, and a controller 20.

(2.1) Power Amplifier

The power amplifier 11 illustrated in FIG. 4 is an amplifier that amplifies a transmission signal. The power amplifier 11 is disposed between the signal input terminal 102 and each of the transmission filters 121 to 123 on a transmission path connecting an antenna terminal 101 (described later) and a signal input terminal 102. The power amplifier 11 has an input terminal (not illustrated) and an output terminal (not illustrated). The input terminal of the power amplifier 11 is connected to an external circuit (for example, a signal processing circuit 92) with the signal input terminal 102 interposed therebetween. The output terminal of the power amplifier 11 is connected to the transmission filters 121 to 123. The power amplifier 11 is controlled by, for example, a controller (not illustrated). It suffices that the power amplifier 11 is directly or indirectly connected to any of the transmission filters 121 to 123. In the example in FIG. 4, the power amplifier 11 is connected to any of the transmission filters 121 to 123 with the output matching circuit 15 interposed therebetween. The output matching circuit 15 is disposed between the power amplifier 11 and each of the transmission filters 121 to 123 on the transmission path. The output matching circuit 15 performs impedance matching between the power amplifier 11 and the transmission filters 121 to 123.

(2.2) Transmission Filters

The plurality of transmission filters 121 to 123 illustrated in FIG. 4 are filters that allow transmission signals in respective mutually different communication bands to pass therethrough. Each of the plurality of transmission filters 121 to 123 is disposed between the power amplifier 11 and the first switch 17 on the transmission path. Each of the plurality of transmission filters 121 to 123 allows, to pass therethrough, a transmission signal that is included in radio frequency signals amplified by the power amplifier 11 and that is in the corresponding transmission band in a communication band.

(2.3) Reception Filters

The plurality of reception filters 131 to 133 illustrated in FIG. 4 are filters that allow reception signals in respective mutually different communication bands to pass therethrough. Each of the plurality of reception filters 131 to 133 is disposed between the first switch 17 and the low noise amplifier 14 on a reception path connecting the antenna terminal 101 (described later) and a signal output terminal 103. Each of the plurality of reception filters 131 to 133 allows, to pass therethrough, a reception signal that is included in radio frequency signals input from the antenna terminal 101 and that is in the corresponding reception band in the communication band.

(2.4) Low Noise Amplifier

The low noise amplifier 14 illustrated in FIG. 4 is an amplifier that amplifies a reception signal with low noise. The low noise amplifier 14 is disposed between each of the reception filters 131 to 133 and the signal output terminal 103 on the reception path. The low noise amplifier 14 has an input terminal (not illustrated) and an output terminal (not illustrated). The input terminal of the low noise amplifier 14 is connected to the input matching circuit 16. The output terminal of the low noise amplifier 14 is connected to an external circuit (for example, the signal processing circuit 92) with the signal output terminal 103 interposed therebetween.

(2.5) Output Matching Circuit

As illustrated in FIG. 4, the output matching circuit 15 is disposed between the power amplifier 11 and each of the transmission filters 121 to 123 on the transmission path. The output matching circuit 15 is a circuit for performing impedance matching between the power amplifier 11 and each of the transmission filters 121 to 123.

The output matching circuit 15 includes an inductor. The inductor is provided on the output side of the power amplifier 11 on the transmission path. The configuration of the output matching circuit 15 is not limited to that including one inductor. For example, the output matching circuit 15 may include a plurality of inductors and may include a plurality of inductors and a plurality of capacitors. In short, the output matching circuit 15 includes at least one inductor.

(2.6) Input Matching Circuit

As illustrated in FIG. 4, the input matching circuit 16 is disposed between each of the reception filters 131 to 133 and the low noise amplifier 14 on the reception path. The input matching circuit 16 is a circuit for performing impedance matching between each of the reception filters 131 to 133 and the low noise amplifier 14.

The input matching circuit 16 includes an inductor. The inductor is provided on the input side of the low noise amplifier 14 on the reception path. The configuration of the input matching circuit 16 is not limited to that including one inductor. For example, the input matching circuit 16 may include a plurality of inductors and may include a plurality of inductors and a plurality of capacitors. In short, the input matching circuit 16 includes at least one inductor.

(2.7) First Switch

The first switch 17 illustrated in FIG. 4 performs switching of a transmission filter to be connected to the antenna terminal 101 from among the plurality of transmission filters 121 to 123. The first switch 17 also performs switching of a reception filter to be connected to the antenna terminal 101 from among the plurality of reception filters 131 to 133. The first switch 17 is a switch for performing switching of a path for connection to an antenna 91. The first switch 17 has a common terminal 171 and a plurality of (in the illustrated example, three) selection terminals 172 to 174. The common terminal 171 is connected to the antenna terminal 101. Each of the plurality of selection terminals 172 to 174 is connected to at least one of the plurality of transmission filters 121 to 123 or the plurality of reception filters 131 to 133. In the example in FIG. 4, each of the plurality of selection terminals 172 to 174 is connected to one of the plurality of reception filters 131 to 133 and one of the plurality of transmission filters 121 to 123.

The first switch 17 performs switching of a state of connection between the common terminal 171 and one of the plurality of selection terminals 172 to 174. The first switch 17 is controlled by, for example, the signal processing circuit 92. The first switch 17 electrically connects the common terminal 171 and at least one of the plurality of selection terminals 172 to 174 in accordance with a control signal from a RF signal processing circuit 93 of the signal processing circuit 92.

(2.8) Second Switch

The second switch 18 illustrated in FIG. 4 performs switching of a transmission filter to be connected to the power amplifier 11 from among the plurality of transmission filters 121 to 123. The second switch 18 is a switch for performing switching of a path for connection to the power amplifier 11. The second switch 18 has a common terminal 181 and a plurality of (in the illustrated example, three) selection terminals 182 to 184. The common terminal 181 is connected to the power amplifier 11. Each of the plurality of selection terminals 182 to 184 is connected to at least one of the plurality of transmission filters 121 to 123. In the example in FIG. 4, each of the plurality of selection terminals 182 to 184 is connected to one of the plurality of transmission filters 121 to 123. In more detail, the plurality of selection terminals 182 to 184 are connected to the plurality of transmission filters 121 to 123 on a one-to-one basis.

The second switch 18 performs switching of a state of connection between the common terminal 181 and one of the plurality of selection terminals 182 to 184. The second switch 18 is controlled by, for example, the signal processing circuit 92. The second switch 18 electrically connects the common terminal 181 and at least one of the plurality of selection terminals 182 to 184 in accordance with a control signal from the RF signal processing circuit 93 of the signal processing circuit 92.

(2.9) Third Switch

The third switch 19 illustrated in FIG. 4 performs switching of a reception filter to be connected to the low noise amplifier 14 from among the plurality of reception filters 131 to 133. The third switch 19 is a switch for performing switching of a path for connection to the low noise amplifier 14. The third switch 19 has a common terminal 191 and a plurality of (in the illustrated example, three) selection terminals 192 to 194. The common terminal 191 is connected to the low noise amplifier 14. Each of the plurality of selection terminals 192 to 194 is connected to at least one of the plurality of reception filters 131 to 133. In the example in FIG. 4, each of the plurality of selection terminals 192 to 194 is connected to one of the plurality of reception filters 131 to 133. In more detail, the plurality of selection terminals 192 to 194 are connected to the plurality of reception filters 131 to 133 on a one-to-one basis.

The third switch 19 performs switching of a state of connection between the common terminal 191 and one of the plurality of selection terminals 192 to 194. The third switch 19 is controlled by, for example, the signal processing circuit 92. The third switch 19 electrically connects the common terminal 191 and at least one of the plurality of selection terminals 192 to 194 in accordance with a control signal from the RF signal processing circuit 93 of the signal processing circuit 92.

(2.10) Controller

The controller 20 controls the power amplifier 11 in accordance with a control signal from the signal processing circuit 92. The controller 20 also controls the electronic components such as the low noise amplifier 14 and the first to third switches 17, 18, and 19 in accordance with a control signal from the signal processing circuit 92. The controller 20 is electrically connected to the electronic components described above (such as the power amplifier 11, the low noise amplifier 14, and the first to third switches 17, 18, and 19).

(2.11) External Connection Terminals

A plurality of external connection terminals 10 are each a terminal for electrical connection to the external circuit (for example, the signal processing circuit 92), the antenna 91, and the like as illustrated in FIG. 4. The plurality of external connection terminals 10 include the antenna terminal 101, the signal input terminal 102, the signal output terminal 103, an input terminal 104, and the ground terminal.

The antenna terminal 101 is connected to the antenna 91. In the radio frequency module 1, the antenna terminal 101 is connected to the first switch 17. The antenna terminal 101 is also connected to the plurality of transmission filters 121 to 123 and the plurality of reception filters 131 to 133 with the first switch 17 interposed therebetween.

The signal input terminal 102 is a terminal through which a transmission signal from the external circuit (for example, the signal processing circuit 92) is input to the radio frequency module 1. In the radio frequency module 1, the signal input terminal 102 is connected to the power amplifier 11.

The signal output terminal 103 is a terminal through which a reception signal from the low noise amplifier 14 is output to the external circuit (for example, the signal processing circuit 92). In the radio frequency module 1, the signal output terminal 103 is connected to the low noise amplifier 14.

The input terminal 104 is a terminal through which a control signal from the external circuit (for example, the signal processing circuit 92) is input to the radio frequency module 1. In the radio frequency module 1, the input terminal 104 is connected to the controller 20.

### (3) Structure of Radio Frequency Module

Hereinafter, the structure of the radio frequency module 1 according to this embodiment will be described with reference to the drawings.

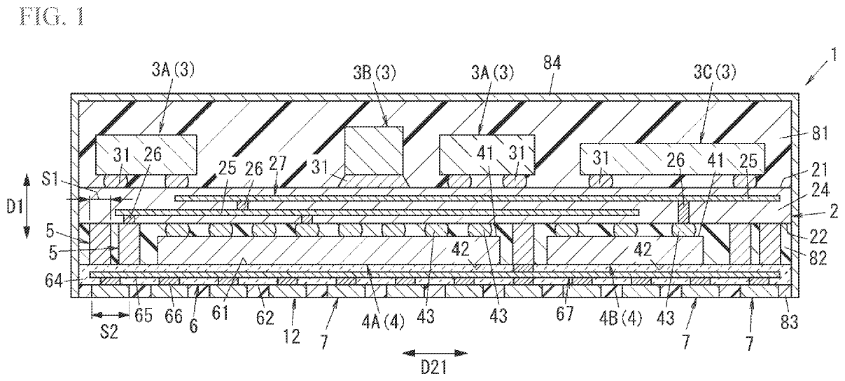

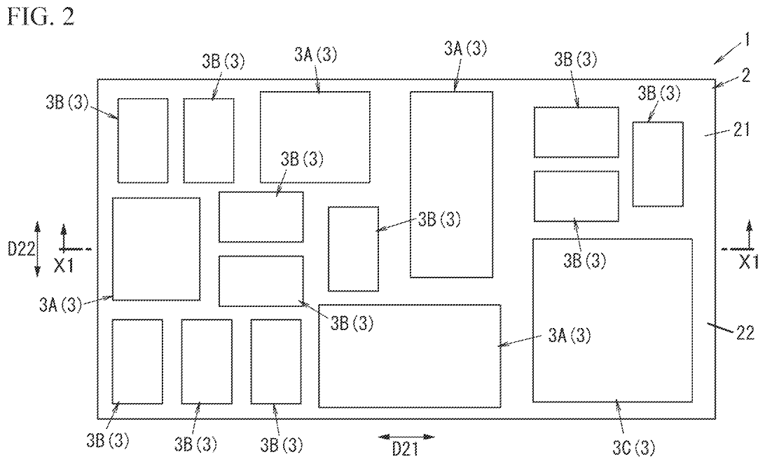

As illustrated in FIGS. 1 to 3, the radio frequency module 1 includes a mounting substrate 2, a plurality of first electronic components 3, a plurality of second electronic components 4, a plurality of connection terminals 5, a base material 6, and a plurality of external connection electrodes 7. The base material 6 and the plurality of external connection electrodes 7 form a wiring layer (also referred to as a rewiring layer) 12. The wiring layer 12 thus includes the base material 6 and the plurality of external connection electrodes 7. The wiring layer 12 faces a second main surface of the mounting substrate 2 with the second electronic components 4 interposed therebetween and is in contact with the plurality of connection terminals 5. The radio frequency module 1 also includes a first resin layer 81, a second resin layer 82, a third resin layer 83, and a shield layer 84. FIG. 1 is a cross-sectional view taken along X1-X1 in FIG. 2.

In the following description, a thickness direction of the mounting substrate 2 is described as a thickness direction D1 (see FIG. 1). In addition, a direction parallel to one side of the mounting substrate 2 (any of right and left directions in the drawing in FIG. 2) in a plan view in the thickness direction D1 of the mounting substrate 2 is described as a first direction D21. A direction orthogonal to both of the thickness direction D1 and the first direction D21 (any of up and down directions in the drawing in FIG. 2) is described as a second direction D22.

The radio frequency module 1 is electrically connectable to an external substrate (not illustrated). The external substrate corresponds to, for example, the mother board of the communication apparatus 9 such as a mobile phone or communication equipment. The phrase “the radio frequency module 1 is electrically connectable to an external substrate” includes not only a case where the radio frequency module 1 is directly mounted on the external substrate but also a case where the radio frequency module 1 is indirectly mounted on the external substrate. The case where the radio frequency module 1 is indirectly mounted on the external substrate is a case the radio frequency module 1 is mounted on a different radio frequency module mounted on the external substrate, or the like.

(3.1) Mounting Substrate

As illustrated in FIG. 1, the mounting substrate 2 has a first main surface 21 and a second main surface 22. The first main surface 21 and the second main surface 22 are opposite to each other in the thickness direction D1 of the mounting substrate 2. The second main surface 22 faces the external substrate if the radio frequency module 1 is provided on the external substrate (not illustrated). The mounting substrate 2 is a double-sided mounting substrate the first main surface 21 and the second main surface 22 of which have electronic components mounted thereon.

The mounting substrate 2 is a multi-layer substrate in which a plurality of dielectric layers are laminated. The mounting substrate 2 has dielectric layers 24, a plurality of conductive layers 25, and a plurality of via conductors (including a through hole electrode) 26. The plurality of conductive layers 25 include a ground layer having a ground potential. The plurality of via conductors 26 are used for electrical connection between the conductive layers 25. The plurality of via conductors 26 are used for electrical connection between elements (including the electronic components described above) mounted on each of the first main surface 21 and the second main surface 22 and the conductive layers 25 of the mounting substrate 2. The plurality of via conductors 26 are used for electrical connection between elements mounted on the first main surface 21 and elements mounted on the second main surface 22 and for electrical connection between the conductive layers 25 of the mounting substrate 2 and the connection terminals 5.

The first main surface 21 of the mounting substrate 2 has the plurality of first electronic components 3 disposed thereon. The second main surface 22 of the mounting substrate 2 has the second electronic components 4 disposed thereon. Further, the second main surface 22 of the mounting substrate 2 has the plurality of connection terminals 5 disposed thereon.

The plurality of conductive layers 25 and the plurality of via conductors 26 form a first conductive member 27. The mounting substrate 2 thus has a first insulating member (the plurality of dielectric layers 24) and the first conductive member 27. The first electronic components 3 are connected to the first conductive member 27 with bumps 31 interposed therebetween. The second electronic components 4 are connected to the first conductive member 27 with bumps 43 interposed therebetween.

(3.2) First Electronic Components

As illustrated in FIGS. 1 and 2, the plurality of first electronic components 3 are disposed on the first main surface 21 of the mounting substrate 2. In the example in FIG. 1, the first electronic components 3 are mounted on the first main surface 21 of the mounting substrate 2. The first electronic components 3 are mounted on the first main surface 21 of the mounting substrate 2 with, for example, the bumps 31 interposed therebetween. In each first electronic component 3, part of the first electronic component 3 may be mounted on the first main surface 21 of the mounting substrate 2, and the other part of the first electronic component 3 may be mounted in the mounting substrate 2. In short, in the mounting substrate 2, the first electronic component 3 is disposed closer to the first main surface 21 than to the second main surface 22 and at least has the part mounted on the first main surface 21.

First electronic components 3A of the plurality of first electronic components 3 are, for example, the transmission filters 121 to 123. Each of the plurality of transmission filters 121 to 123 is an acoustic wave filter including, for example, a plurality of serial arm resonators and a plurality of parallel arm resonators. The acoustic wave filter is, for example, a surface acoustic wave (SAW: Surface Acoustic Wave) filter that uses a surface acoustic wave. Further, each of the plurality of transmission filters 121 to 123 may include at least one of an inductor or a capacitor that are connected in series to any of a plurality of serial arm resonators and may include an inductor or a capacitor that is connected in series to any of a plurality of parallel arm resonators.

Each of first electronic components 3B of the plurality of first electronic components 3 is, for example, an inductor or a capacitor of the output matching circuit 15 or an inductor or a capacitor of the input matching circuit 16. A first electronic component 3C of the plurality of first electronic components 3 is, for example, a power amplifier.

(3.3) Second Electronic Components

As illustrated in FIG. 1, the second electronic components 4 are disposed on the second main surface 22 of the mounting substrate 2. In the example in FIG. 1, the second electronic components 4 are mounted on, for example, the second main surface 22 of the mounting substrate 2. The second electronic components 4 are mounted on the second main surface 22 of the mounting substrate 2 with, for example, the bumps 43 interposed therebetween. The second electronic components 4 are thus connected to the first conductive member 27 of the mounting substrate 2 with, for example, the bumps 43 interposed therebetween. Part of each second electronic component 4 may be disposed on the second main surface 22 of the mounting substrate 2, and the other part of the second electronic components 4 may be mounted in the mounting substrate 2. In short, in the mounting substrate 2, the second electronic component 4 is located closer to the second main surface 22 than to the first main surface 21 and at least has the part mounted on the second main surface 22. A plurality of second electronic components 4A of the plurality of second electronic components 4 are the low noise amplifier 14. A plurality of second electronic components 4B of the plurality of second electronic components 4 are the first switch 17.

(3.4) Connection Terminals

As illustrated in FIG. 1, the plurality of connection terminals 5 are a terminal for electrically connecting the mounting substrate 2 and the wiring layer 12 (in more detail, the base material 6).

The plurality of connection terminals 5 are disposed on the second main surface 22 of the mounting substrate 2. The plurality of connection terminals 5 are columnar (for example, cylindrical) electrodes provided on the second main surface 22 of the mounting substrate 2. The connection terminals 5 are thus long. The plurality of connection terminals 5 are disposed on the second main surface 22 of the mounting substrate 2 and are connected to the mounting substrate 2 and the base material 6. The plurality of connection terminals 5 thus electrically connects the mounting substrate 2 and the base material 6. The plurality of connection terminals 5 are connected to the first conductive member 27 of the mounting substrate 2 and a second conductive member (described later) of the base material 6. The plurality of connection terminals 5 are each disposed between the plurality of second electronic components 4 or on the peripheral edge of the second main surface 22 of the mounting substrate 2. That is, at least one of the plurality of connection terminals 5 is disposed between the plurality of second electronic components 4. This enables the connection terminal 5 to be disposed by using a space between the plurality of second electronic components 4.

The material of the plurality of connection terminals 5 is, for example, a metal (such as copper or a copper alloy). Each of the plurality of connection terminals 5 has a proximal end portion and a distal end portion in the thickness direction D1 of the mounting substrate 2, the proximal end portion being bonded to the second main surface 22 of the mounting substrate 2 and the distal end portion being located on an opposite side from the proximal end portion. The distal end portion is connected to a third main surface 61 on a mounting substrate 2 side of the base material 6. The distal end portion of each of the plurality of connection terminals 5 may include, for example, a gold-plated layer.

The plurality of connection terminals 5 include a signal terminal, a ground terminal, and a power supply terminal. The signal terminal is a terminal through which signals (such as a transmission signal and a reception signal) flow. The ground terminal is a terminal where a ground potential is kept. The power supply terminal is a terminal through which power current flows and to which a power supply voltage is applied.

(3.5) Base Material

As illustrated in FIG. 1, the base material 6 is a substrate for disposing a conductor for electrically connecting the plurality of connection terminals 5 and the plurality of external connection electrodes. The base material 6 has the third main surface 61 and a fourth main surface 62. The third main surface 61 and the fourth main surface 62 are opposite to each other in the thickness direction (the thickness direction D1 of the mounting substrate 2) of the base material 6. The third main surface 61 is a main surface on the mounting substrate 2 side of the base material 6. The fourth main surface 62 is a main surface on an opposite side of the base material 6 from the mounting substrate 2 side. The fourth main surface 62 faces the external substrate if the radio frequency module 1 is provided on the external substrate (not illustrated). The base material 6 is electrically connected to the plurality of connection terminals 5 on the third main surface 61.

The base material 6 is a multi-layer substrate in which a plurality of dielectric layers are laminated. The base material 6 has a dielectric layer 64, a plurality of conductive layers 65, and a plurality of via conductors 66 (through hole electrodes). The plurality of conductive layers 65 include a ground layer having a ground potential. The plurality of via conductors 66 are used for electrical connection between the conductive layers 65 of the base material 6. The plurality of via conductors 66 are also used for electrical connection between the conductive layers 65 of the base material 6 and the external connection electrodes 7. The via conductors 66 are also used for electrical connection between the conductive layers 65 of the base material 6 and the connection terminals 5.

The distal end portions of the plurality of connection terminals 5 are disposed on the third main surface 61 of the base material 6. The plurality of external connection electrodes 7 are disposed on the fourth main surface 62 of the base material 6. The plurality of external connection electrodes 7 are electrically connected to at least one of the plurality of connection terminals 5 with the via conductors 66 and the conductive layers 65 interposed therebetween. The third main surface 61 of the base material 6 faces the entire second main surface 22 of the mounting substrate 2 in the thickness direction D1 of the mounting substrate 2. Accordingly, the base material 6 can be expanded to the same area as that of the mounting substrate 2 in a plan view in the thickness direction D1 of the mounting substrate 2. This enables a higher degree of freedom in disposing the plurality of external connection electrodes 7 on the base material 6.

The base material 6 is in contact with the plurality of second electronic components 4 (for example, all of the second electronic components 4). In more detail, the third main surface 61 of the base material 6 is in contact with a sixth main surface 42 (a main surface on an opposite side from the mounting substrate 2 side) of each of the plurality (all) of second electronic components 4. In the contact, the base material 6 and the second electronic components 4 do not have to be electrically connected, and the base material 6 and the second electronic components 4 are thermally coupled.

The plurality of conductive layers 65 and the plurality of via conductors 66 form a second conductive member 67. The base material 6 thus has the second insulating member (the dielectric layer 64) and the second conductive member 67. The second conductive member 67 is connected to the first conductive member 27 of the mounting substrate 2 with at least one of the plurality of connection terminals 5 interposed therebetween. The second conductive member 67 is connected to the plurality of external connection electrodes 7.

(3.6) External Connection Electrodes

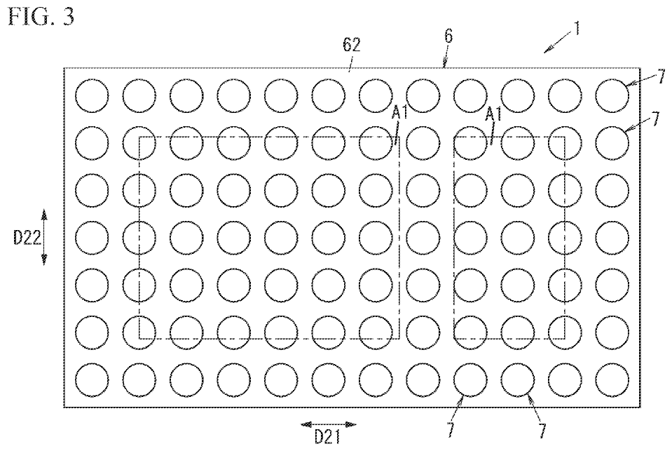

As illustrated in FIGS. 1 and 3, the plurality of external connection electrodes 7 are each a terminal for electrically connecting the base material 6 and the external substrate (not illustrated). The plurality of external connection electrodes 7 form the plurality of external connection terminals 10. The plurality of external connection electrodes 7 are electrically connected to at least one of the plurality of connection terminals 5 with the second conductive member 67 of the base material 6 interposed therebetween. At least one of the plurality of external connection electrodes 7 is connected to the second conductive member 67 of the base material 6. At least one of the plurality of external connection electrodes 7 is thus electrically connected to the first conductive member 27 of the mounting substrate 2 with the second conductive member 67 of the base material 6 and the plurality of connection terminals 5 interposed therebetween. The plurality of external connection electrodes 7 include a ground electrode, a signal electrode, and a power supply electrode. The ground electrode is an electrode having a ground potential. The ground electrode is electrically connected to the ground terminal of a corresponding one of the connection terminal 5 with the ground layer of the base material 6 of the wiring layer 12 interposed therebetween. The signal electrode is an electrode through which signals (a transmission signal and a reception signal) processed by the radio frequency module 1 flow and is electrically connected to the signal terminal of a corresponding one of the connection terminals 5 with one of the conductive layers 65 that is for a signal in the base material 6 interposed therebetween. The power supply electrode is an electrode through which power current of the radio frequency module 1 flows and to which a power supply voltage is applied. The power supply electrode is electrically connected to the power supply terminal of a corresponding one of the connection terminals 5 with one of the conductive layers 65 that is for power supply in the base material 6 interposed therebetween. The signal electrode and the power supply electrode are each a different electrode different from the ground electrode.

The plurality of external connection electrodes 7 are disposed on the fourth main surface 62 of the base material 6. The plurality of external connection electrodes 7 are columnar (for example, cylindrical) electrodes provided on the fourth main surface 62 of the base material 6. The material of the plurality of external connection electrodes 7 is, for example, a metal (such as copper or a copper alloy). Each of the plurality of external connection electrodes 7 has a proximal end portion and a distal end portion in the thickness direction (the thickness direction D1 of the mounting substrate 2) of the base material 6, the proximal end portion being bonded to the fourth main surface 62 of the base material 6, the distal end portion being located on an opposite side from the proximal end portion. The distal end portion of each of the plurality of external connection electrodes 7 may include, for example, a gold-plated layer.

(3.7) Relationship in Connection and Layout Between Substrate and External Connection Electrodes

In this embodiment, as illustrated in FIGS. 1 to 3, the base material 6 is disposed in such a manner that the base material 6 and the mounting substrate 2 sandwich the plurality of connection terminals 5. The base material 6 is electrically connected to the mounting substrate 2 with the plurality of connection terminals 5 interposed therebetween.

In the plan view in the thickness direction D1 of the mounting substrate 2, the plurality of external connection electrodes 7 are disposed in an area A1 (see FIG. 3) included in the fourth main surface 62 of the base material 6 and overlapping with at least the second electronic components 4. In the plan view in the thickness direction D1 of the mounting substrate 2, the second electronic components 4 thus overlap with at least one of the plurality of external connection electrodes 7. The plurality of external connection electrodes 7 are electrically connected to the plurality of connection terminals 5 with the base material 6 interposed therebetween. In the plan view in the thickness direction D1 of the mounting substrate 2, the plurality of external connection electrodes 7 also include an external connection electrode 7 overlapping with one of the plurality of connection terminals 5 (see FIG. 1).

The base material 6 connects the plurality of connection terminals 5 and the external connection electrodes 7. The plurality of connection terminals 5 are connected to the third main surface 61 of the base material 6. In contrast, the plurality of external connection electrodes 7 are disposed on the fourth main surface 62 of the base material 6.

The plurality of external connection electrodes 7 are more than, for example, the plurality of connection terminals 5. The radio frequency module 1 is provided with the plurality of external connection electrodes 7 from the viewpoints of mounting the radio frequency module 1 on the external substrate (mother board), increasing the ground terminals of the radio frequency module 1, and the like.

In the plan view in the thickness direction D1 of the mounting substrate 2, a cross section S1 of each the connection terminal 5 is different from a cross section S2 of each external connection electrode 7. In this embodiment, the cross section S2 of the external connection electrode 7 is larger than, for example, the cross section S1 of the connection terminals 5. That is, the connection terminal 5 is narrower than the external connection electrode 7. This enables a dead space on the second main surface 22 of the mounting substrate 2 to be made smaller than in a case where the connection terminal 5 is wide. In contrast, the area of the external connection electrode 7 can be made larger, and thus connection to the external substrate can be performed stably.

The base material 6 is thinner than the mounting substrate 2 in the thickness direction D1 of the mounting substrate 2. Height reduction in the radio frequency module 1 can thereby be achieved. In more detail, in this embodiment, as to be described later, height reduction in the radio frequency module 1 can be achieved by omitting the second resin layer 82 between the wiring layer 12 and the second electronic components 4. Further, the base material 6 is thinner than the mounting substrate 2, and thereby further height reduction in the radio frequency module 1 can be achieved.

(3.8) First Resin Layer, Second Resin Layer, Third Resin Layer, and Shield Layer

As illustrated in FIG. 1, the first resin layer 81 is disposed on the first main surface 21 of the mounting substrate 2. The first resin layer 81 covers each of the plurality of first electronic components 3. The first resin layer 81 covers the outer circumferential surface of the first electronic component 3 and a main surface on an opposite side of the first electronic component 3 from the mounting substrate 2 side. The first resin layer 81 includes a resin (for example, an epoxy resin). The first resin layer 81 may include a filler in addition to a resin.

As illustrated in FIG. 1, the second resin layer 82 is disposed on the second main surface 22 of the mounting substrate 2. In more detail, the second resin layer 82 is disposed between the mounting substrate 2 and the wiring layer 12 (in more detail, the base material 6). The second resin layer 82 partially covers the second electronic components 4 and the plurality of connection terminals 5. In more detail, the second resin layer 82 covers the outer circumferential surface of each second electronic component 4 but does not cover the main surface (sixth main surface 42) on the opposite side of the second electronic component 4 from the mounting substrate 2 side. The second resin layer 82 covers the outer circumferential surface of each of the plurality of connection terminals 5 but does not cover a distal end surface (an end surface on an opposite side from the mounting substrate 2 side) of the connection terminal 5. The main surface on the opposite side of the second resin layer 82 from the mounting substrate 2 side, the sixth main surface 42 of the second electronic component 4, and the distal end surface of the connection terminal 5 are flush with each other. The base material 6 of the wiring layer 12 is disposed in such a manner as to cover these flush surfaces. The second resin layer 82 includes a resin (for example, an epoxy resin). The second resin layer 82 may include a filler in addition to a resin. The material of the second resin layer 82 may be the same material as or a different material from the material of the first resin layer 81.

As illustrated in FIG. 1, the third resin layer 83 is disposed on the fourth main surface 62 of the base material 6. The third resin layer 83 covers the plurality of external connection electrodes 7. The third resin layer 83 covers the outer circumferential surface of each external connection electrode 7. The third resin layer 83 includes a resin (for example, an epoxy resin). The third resin layer 83 may include a filler in addition to a resin. The material of the third resin layer 83 may be the same material as or a different material from the material of the first resin layer 81. The material of the third resin layer 83 may be the same material as or a different material from the material of the second resin layer 82.

As illustrated in FIG. 1, the shield layer 84 covers the first resin layer 81. The shield layer 84 is conductive. In the radio frequency module 1, the shield layer 84 is provided for electromagnetic shielding inside and outside the radio frequency module 1. The shield layer 84 has a multi-layer structure in which a plurality of metal layers are laminated, but the structure is not limited to this. The shield layer 84 may have a one-metal layer structure. A metal layer includes one or more types of metals. The shield layer 84 covers a main surface on an opposite side of the first resin layer 81 from a mounting substrate 2 side, an outer circumferential surface of the first resin layer 81, and an outer circumferential surface of the mounting substrate 2. The shield layer 84 also covers an outer circumferential surface of the second resin layer 82, an outer circumferential surface of the base material 6, and an outer circumferential surface of the third resin layer 83. The shield layer 84 is in contact with at least part of an outer circumferential surface of the ground layer of the mounting substrate 2. This enables the potential of the shield layer 84 to be equal to the potential of the ground layer. The shield layer 84 is also in contact with at least part of an outer circumferential surface of the ground layer of the base material 6. In this embodiment, the shield layer 86 covers the outer circumferential surface of the third resin layer 83 but does not have to cover the outer circumferential surface of the third resin layer 83.

### (4) Detailed Structure of Radio Frequency Module Components

(4.1) Mounting Substrate

The mounting substrate 2 illustrated in FIGS. 1 to 3 is a multi-layer substrate including, for example, the plurality of dielectric layers 24 and the plurality of conductive layers 25. The plurality of dielectric layers and the plurality of conductive layers 25 are stacked in the thickness direction D1 of the mounting substrate 2. The plurality of conductive layers 25 are each formed into a predetermined pattern determined on a per-layer basis. Each of the plurality of conductive layers 25 includes one or more conductor portions in a plane orthogonal to the thickness direction D1 of the mounting substrate 2. The material of the conductive layer 25 is, for example, copper. The plurality of conductive layers 25 includes the ground layer. In the radio frequency module 1, the plurality of external ground terminals and the ground layer are electrically connected with the via conductors 26 or the like of the mounting substrate 2 interposed therebetween. The mounting substrate 2 is, for example, a low temperature co-fired ceramics (LTCC) substrate. The mounting substrate 2 is not limited to the LTCC substrate and may be, for example, a printed-circuit board, a high temperature co-fired ceramics (HTCC) substrate, or a multi-layer resin substrate.

The mounting substrate 2 is not limited to the LTCC substrate and may be, for example, a wiring structure. The wiring structure is, for example, a multi-layer structure. The multi-layer structure includes at least one dielectric layer 24 and at least one conductive layer 25. The dielectric layer 24 is formed into a predetermined pattern. In the case of the plurality of dielectric layers 24, the plurality of dielectric layers 24 are each formed into a predetermined pattern determined on a per-layer basis. The conductive layer 25 is formed into a predetermined pattern different from the predetermined pattern of the dielectric layer 24. In the case of the plurality of conductive layers 25, the plurality of conductive layers 25 are each formed into a predetermined pattern determined on a per-layer basis. The conductive layers 25 may include one or more rewiring portions. In the wiring structure, a first surface of two surfaces opposite to each other in a thickness direction of the multi-layer structure is the first main surface 21 of the mounting substrate 2, and a second surface is the second main surface 22 of the mounting substrate 2. The wiring structure may be, for example, an interposer. The interposer may be an interposer using a silicon substrate and may also be a substrate composed of a plurality of layers.

The first main surface 21 and the second main surface 22 of the mounting substrate 2 are away from each other in the thickness direction D1 of the mounting substrate 2 and cross the thickness direction D1 of the mounting substrate 2. The first main surface 21 of the mounting substrate 2 is, for example, orthogonal to the thickness direction D1 of the mounting substrate 2 but may include a side surface or the like of a conductor portion, for example, as a surface not orthogonal to the thickness direction D1. The second main surface 22 of the mounting substrate 2 is orthogonal to, for example, the thickness direction D1 of the mounting substrate 2 but may include a side surface or the like of a conductor portion, for example, as a surface not orthogonal to the thickness direction D1. The first main surface 21 and the second main surface 22 of the mounting substrate 2 may have minute unevenness, or a recessed portion or a projecting portion may be formed thereon.

(4.2) Filters

a detailed structure of the plurality of transmission filters 121 to 123 and the plurality of reception filters 131 to 133 that are illustrated in FIG. 4 will be described. In the following description, the transmission filters 121 to 123 and the reception filters 131 to 133 are not discriminated from each other and are each referred to as a filter.

The filter is a filter as one chip. In the filters herein, for example, each of a plurality of serial arm resonators and a plurality of parallel arm resonators is formed from an acoustic wave resonator. In this case, the filter includes, for example, a substrate, a piezoelectric layer, and a plurality of IDT electrodes (Interdigital Transducer). The substrate has a first surface and a second surface. The piezoelectric layer is provided on the first surface of the substrate. The piezoelectric layer is provided on a low-acoustic-velocity film. The plurality of IDT electrodes are provided on the piezoelectric layer. The low-acoustic-velocity film is herein provided on the substrate directly or indirectly. The piezoelectric layer is provided on the low-acoustic-velocity film directly or indirectly. In the low-acoustic-velocity film, the acoustic velocity of a bulk wave propagating through the low-acoustic-velocity film is lower than the acoustic velocity of an acoustic wave propagating through the piezoelectric layer. In the substrate, the acoustic velocity of a bulk wave propagating through the substrate is higher than the acoustic velocity of the acoustic wave propagating through the piezoelectric layer. The material of the piezoelectric layer is, for example, lithium tantalate. The material of the low-acoustic-velocity film is, for example, silicon oxide. The substrate is, for example, a silicon substrate. If the wavelength of an acoustic wave determined by the electrode finger period of the IDT electrodes is k, the thickness of the piezoelectric layer is, for example, lower than or equal to 3.5λ. The thickness of the low-acoustic-velocity film is, for example, lower than or equal to 2.0λ

The piezoelectric layer may be formed from, for example, one of lithium tantalate, lithium niobate, zinc oxide, aluminum nitride, and PZT. The low-acoustic-velocity film may include at least one type of material selected from the group consisting of silicon oxide, glass, silicon oxynitride, tantalum pentoxide, and a compound formed by adding fluorine, carbon, or boron to silicon oxide. In addition, the substrate may include at least one type of material selected from the group consisting of silicon, aluminum nitride, aluminum oxide, silicon carbide, silicon nitride, sapphire, lithium tantalate, lithium niobate, crystal, alumina, zirconia, cordierite, mullite, steatite, forsterite, magnesia, and diamond.

The filter further includes, for example, a spacer layer and a cover member. The spacer layer and the cover member are disposed on the first surface of the substrate. The spacer layer surrounds the plurality of IDT electrodes in a plan view in the thickness direction of the substrate. The spacer layer is of a frame shape (rectangular frame shape) in the plan view in the thickness direction of the substrate. The spacer layer is electrically insulative. The material of the spacer layer is, for example, a synthetic resin such as an epoxy resin or polyimide. The cover member has a plate shape. The shape of the cover member is a rectangle in the plan view in the thickness direction of the substrate but is not limited to this. The shape may be, for example, a square. In the filter, the outer size of the cover member, the outer size of the spacer layer, and the outer size of the cover member are substantially identical in the plan view in the thickness direction of the substrate. The cover member is located on the spacer layer in such a manner as to face the substrate in the thickness direction of the substrate. The cover member overlaps with the plurality of IDT electrodes in the thickness direction of the substrate and is away from the plurality of IDT electrodes in the thickness direction of the substrate. The cover member is electrically insulative. The material of the cover member is, for example, a synthetic resin such as an epoxy resin or polyimide. The filter has a space surrounded by the substrate, the spacer layer, and the cover member. The filter has a gas in the space. The gas is, for example, air or an inert gas (for example, a nitrogen gas). A plurality of terminals are exposed from the cover member. The plurality of terminals are each, for example, a bump. The bump is, for example, a solder bump. The bump is not limited to the solder bump and may be, for example, a gold bump.

The filter may include, for example, a close-contact layer interposed between the low-acoustic-velocity film and the piezoelectric layer. The close-contact layer is formed from, for example, a resin (an epoxy resin or a polyimide resin). The filter may also include a dielectric film between the low-acoustic-velocity film and the piezoelectric layer, on the piezoelectric layer, or under the low-acoustic-velocity film.

The filter may also include, for example, a high-acoustic-velocity film interposed between the substrate and the low-acoustic-velocity film. The high-acoustic-velocity film is herein provided on the substrate directly or indirectly. The low-acoustic-velocity film is provided on the high-acoustic-velocity film directly or indirectly. The piezoelectric layer is provided on the low-acoustic-velocity film directly or indirectly. In the high-acoustic-velocity film, the acoustic velocity of a bulk wave propagating through the high-acoustic-velocity film is higher than the acoustic velocity of the acoustic wave propagating through the piezoelectric layer. In the low-acoustic-velocity film, the acoustic velocity of the bulk wave propagating through the low-acoustic-velocity film is lower than the acoustic velocity of the acoustic wave propagating through the piezoelectric layer.

The high-acoustic-velocity film is formed from: a piezoelectric body such as diamondlike carbon, aluminum nitride, aluminum oxide, silicon carbide, silicon nitride, silicon, sapphire, lithium tantalate, lithium niobate, or crystal; any of various ceramics such as alumina, zirco+nia, cordierite, mullite, steatite, and forsterite; magnesia; diamond; a material having any of the materials described above serving as a main component; or a material having a mixture of the materials described above serving as a main component.

The high-acoustic-velocity film has a function of confining the acoustic wave in the piezoelectric layer and the low-acoustic-velocity film. Accordingly, regarding the thickness of the high-acoustic-velocity film, the thicker the high-acoustic-velocity film, the more desirable the high-acoustic-velocity film. The piezoelectric substrate may have a close-contact layer, a dielectric film, or another layer as a film other than the high-acoustic-velocity film, the low-acoustic-velocity film, and the piezoelectric layer.

Each of the plurality of serial arm resonators and the plurality of parallel arm resonators is not limited to the acoustic wave resonator described above and may be, for example, a SAW resonator or a bulk acoustic wave (BAW) resonator. The SAW resonator herein includes, for example, the piezoelectric substrate and the IDT electrodes disposed on the piezoelectric substrate. If the plurality of serial arm resonators and the plurality of parallel arm resonators are each configured as the SAW resonator, the filter has, on one piezoelectric substrate, the plurality of IDT electrodes for the plurality of respective serial arm resonators and the plurality of IDT electrodes for the plurality of respective parallel arm resonators. The piezoelectric substrate is, for example, a lithium tantalate substrate or a lithium niobate substrate.

(4.3) Power Amplifier

The power amplifier 11 illustrated in FIG. 4 is, for example, an IC as one chip including a substrate and an amplification functional unit. The substrate has a first surface and a second surface that are opposite from each other. The substrate is, for example, a gallium arsenide substrate. The amplification functional unit includes at least one transistor formed on the first surface of the substrate. The amplification functional unit is a functional unit having a function of amplifying a transmission signal in a predetermined frequency band. The transistor is, for example, a heterojunction bipolar transistor (HBT). In the power amplifier 11, a power supply voltage from the power supply circuit (not illustrated) is applied between a collector and an emitter of the HBT. The power amplifier 11 may include, for example, a capacitor for cutting direct current in addition to the amplification functional unit. Flip-chip mounting of the power amplifier 11 is performed on the first main surface 21 of the mounting substrate 2, for example, to cause the first surface of the substrate to face the first main surface 21 of the mounting substrate 2. In the plan view in the thickness direction D1 of the mounting substrate 2, the power amplifier 11 has a square outline.

(4.4) Low Noise Amplifier

The low noise amplifier 14 illustrated in FIG. 4 is, for example, an IC component including a substrate and an amplification functional unit. The substrate has a first surface and a second surface that are opposite from each other. The substrate is, for example, a silicon substrate. The amplification functional unit is formed on the first surface of the substrate. The amplification functional unit is a functional unit having a function of amplifying a reception signal in a predetermined frequency band. Flip-chip mounting of the low noise amplifier 14 is performed on the second main surface 22 of the mounting substrate 2, for example, to cause the first surface of the substrate to face the second main surface 22 of the mounting substrate 2.

(4.5) Base Material

The base material 6 illustrated in FIG. 1 is, for example, a multi-layer substrate including the plurality of dielectric layers 64 and the plurality of conductive layers 65. The plurality of dielectric layers and the plurality of conductive layers 65 are stacked in a thickness direction (the thickness direction D1 of the mounting substrate 2) of the base material 6. The plurality of conductive layers 65 are each formed into a predetermined pattern determined on a per-layer basis. Each of the plurality of conductive layers 65 includes one or more conductor portions in a plane orthogonal to the thickness direction of the base material 6. The material of the conductive layer 65 is, for example, copper. The plurality of conductive layers 65 includes the ground layer. In the radio frequency module 1, the plurality of external ground terminals and the ground layer are electrically connected with the via conductors 66 or the like of the base material 6 interposed therebetween. The base material 6 is, for example, a LTCC substrate. The base material 6 is not limited to the LTCC substrate and may be, for example, a printed-circuit board, a HTCC substrate, or a multi-layer resin substrate.

The base material 6 is not limited to the LTCC substrate and may be, for example, a wiring structure. The wiring structure is, for example, a multi-layer structure. The multi-layer structure includes at least one insulating layer and at least one conductive layer. The insulating layer is formed into a predetermined pattern. In a case of a plurality of insulating layers, the plurality of insulating layers are each formed into a predetermined pattern determined on a per-layer basis. The conductive layer is formed into a predetermined pattern different from the predetermined pattern of the insulating layer. In a case of a plurality of conductive layers, the plurality of conductive layers are each formed into a predetermined pattern determined on a per-layer basis. The conductive layers may include one or more rewiring portions. In the wiring structure, a first surface of two surfaces opposite to each other in a thickness direction of the multi-layer structure is the third main surface 61 of the base material 6, and a second surface is the fourth main surface 62 of the base material 6. The wiring structure may be, for example, an interposer. The interposer may be an interposer using a silicon substrate and may also be a substrate composed of a plurality of layers.

The third main surface 61 and the fourth main surface 62 of the base material 6 are away from each other in the thickness direction of the base material 6 and cross the thickness direction of the base material 6. The third main surface 61 of the base material 6 is, for example, orthogonal to the thickness direction of the base material 6 but may include a side surface or the like of a conductor portion, for example, as a surface not orthogonal to the thickness direction. The fourth main surface 62 of the base material 6 is orthogonal to, for example, the thickness direction of the base material 6 but may include a side surface or the like of a conductor portion, for example, as a surface not orthogonal to the thickness direction. The third main surface 61 and the fourth main surface 62 of the base material 6 may have minute unevenness, or a recessed portion or a projecting portion may be formed thereon.

(4.6) Layout Relationship Between Wiring Layer and Second Electronic Components and Function of Wiring Layer

In this embodiment, as illustrated in FIG. 1, the wiring layer 12 is disposed in such a manner as to be in contact with the plurality of second electronic components 4 (in more detail, the sixth main surface 42). That is, the second resin layer 82 is not present between the wiring layer 12 and the second electronic components 4. The omission of the second resin layer 82 between the wiring layer 12 and the second electronic components 4 as described above enables the height of the radio frequency module 1 to be reduced by an amount corresponding to the omission.

The radio frequency module 1 is provided with the wiring layer 12. Accordingly, a higher degree of freedom in designing the external connection electrodes 7 can be achieved without necessarily being restricted by the layout of the connection terminals 5 on the second main surface 22 of the mounting substrate 2. Specifically, a higher degree of freedom in the layout of the external connection electrodes 7 and a higher degree of freedom in the size of the external connection electrodes 7 (for example, the size of a cross section) can be achieved. In the degree of freedom in the layout of the external connection electrodes 7, providing the wiring layer 12 enables the external connection electrodes 7 to be disposed not only not to overlap with the second electronic components 4 in the plan view in the thickness direction D1 of the mounting substrate 2 but also to overlap with the second electronic components 4. In the degree of freedom in the size of each external connection electrode 7, the cross section S2 of the external connection electrode 7 can be made different from the cross section S1 of the connection terminal 5. For example, the cross section S2 of the external connection electrode 7 can also be made larger than the cross section S1 of the connection terminal 5.

In the radio frequency module 1, the wiring layer 12 is in contact with the second electronic components 4 (in more detail, the sixth main surface 42). Accordingly, heat generated from the second electronic components 4 becomes easy to transmit toward the wiring layer 12 and thus becomes difficult to stay inside the mounting substrate 2, and characteristics deterioration due to heat in the radio frequency module 1 can thereby be prevented. In more detail, consider a radio frequency module in a comparative example. In the radio frequency module in the comparative example, the wiring layer 12 is not in contact with the second electronic components 4. In the radio frequency module in the comparative example, heat generated from the second electronic components 4 flows to the mounting substrate 2 through the bumps 43 of the second electronic components 4, passes from the mounting substrate 2 through the connection terminals 5 and the wiring layer 12, and is radiated from the external connection electrodes 7. Accordingly, the heat generated from the second electronic components 4 is easy to stay inside the mounting substrate 2. In contrast, in the radio frequency module 1, the wiring layer 12 is in contact with the second electronic components 4. Accordingly, the heat generated from the second electronic components 4 is easy to radiate from the external connection electrodes 7, passing from the second electronic components 4 through the wiring layer 12, and is difficult to flow from the second electronic components 4 to the mounting substrate 2. Accordingly, the heat generated from the second electronic components 4 becomes difficult to stay inside the mounting substrate 2, and the characteristics deterioration due to heat in the radio frequency module 1 can thereby be prevented.

The radio frequency module in the comparative example above has only one heat radiation path as a heat radiation path through which the heat generated from the second electronic components 4 is radiated. In contrast, the radio frequency module 1 of this embodiment has two heat radiation paths (a first heat radiation path and a second heat radiation path) as the heat radiation path through which the heat generated from the second electronic components 4 is radiated. The first heat radiation path is a heat radiation path through which the heat generated from the second electronic components 4 flows to the mounting substrate 2 through the bumps 43 of the second electronic components 4, passes from the mounting substrate 2 through the connection terminals 5 and the wiring layer 12, and is radiated from the external connection electrodes 7. The second heat radiation path is a heat radiation path through which the heat generated from the second electronic components 4 is directly transmitted toward the wiring layer 12 and is radiated. The heat radiation properties of the radio frequency module 1 is thus improved from the heat radiation properties of the radio frequency module in the comparative example.

### (5) Communication Apparatus

As illustrated in FIG. 4, the communication apparatus 9 includes the radio frequency module 1, the antenna 91, and the signal processing circuit 92.

(5.1) Antenna

The antenna 91 is connected to the antenna terminal 101 of the radio frequency module 1. The antenna 91 has a transmission function of radiating, as a radio wave, a transmission signal output from the radio frequency module 1 and a reception function of receiving a reception signal as a radio wave from an external apparatus and then outputting the signal to the radio frequency module 1.

(5.2) Signal Processing Circuit

The signal processing circuit 92 includes the RF signal processing circuit 93, and a baseband signal processing circuit 94. The signal processing circuit 92 processes signals passing through the radio frequency module 1. In more detail, the signal processing circuit 92 processes transmission signals and reception signals.

The RF signal processing circuit 93 is, for example, a radio frequency integrated circuit (RFIC) and performs signal processing of a radio frequency signal.

The RF signal processing circuit 93 performs signal processing such as upconverting of a radio frequency signal output from the baseband signal processing circuit 94 and outputs the radio frequency signal subjected to the signal processing to the radio frequency module 1. Specifically, the RF signal processing circuit 93 performs the signal processing such as upconverting of a transmission signal output from the baseband signal processing circuit 94 and outputs the transmission signal subjected to the signal processing to the transmission path of the radio frequency module 1.

The RF signal processing circuit 93 performs signal processing such as downconverting of a radio frequency signal output from the radio frequency module 1 and outputs the radio frequency signal subjected to the signal processing to the baseband signal processing circuit 94. Specifically, the RF signal processing circuit 93 performs the signal processing of a reception signal output from the reception path of the radio frequency module 1 and outputs the reception signal subjected to the signal processing to the baseband signal processing circuit 94.

The baseband signal processing circuit 94 is, for example, a baseband integrated circuit (BBIC) and performs predetermined signal processing of a signal transmitted from outside the signal processing circuit 92. The received signal processed by the baseband signal processing circuit 94 is used, for example, as an image signal for image displaying as an image signal or an audio signal for calling.

The RF signal processing circuit 93 also has a function as a controller that controls the connection of the first switch 17, the second switch 18, and the third switch 19 of the radio frequency module 1 on the basis of the used communication band (frequency band). Specifically, the RF signal processing circuit 93 performs switching of connection of the first switch 17, the second switch 18, and the third switch 19 of the radio frequency module 1 by using a control signal (not illustrated). The controller may be provided outside the RF signal processing circuit 93 and may be provided to, for example, the radio frequency module 1 or the baseband signal processing circuit 94.

### (6) Effects

This embodiment includes the mounting substrate 2, the first electronic components 3, the second electronic components 4, the plurality of connection terminals 5, and the wiring layer 12. The mounting substrate 2 has the first main surface 21 and the second main surface 22 opposite to each other. The first electronic components 3 are disposed on the first main surface 21 of the mounting substrate 2. The second electronic components 4 are disposed on the second main surface 22 of the mounting substrate 2. The plurality of connection terminals 5 are disposed on the second main surface 22 of the mounting substrate 2 and are connected to the mounting substrate 2. The wiring layer 12 faces the second main surface 22 of the mounting substrate 2 with the second electronic components 4 interposed therebetween and is connected to the plurality of connection terminals 5. The second electronic components 4 are located between the mounting substrate 2 and the wiring layer 12. The wiring layer 12 has the base material 6 and the plurality of external connection electrodes 7. The base material 6 has the third main surface 61 and the fourth main surface 62 opposite to each other and is connected to the plurality of connection terminals 5 with the third main surface 61 interposed therebetween. The plurality of external connection electrodes 7 are disposed on the fourth main surface 62 of the base material 6. The mounting substrate 2 has the first conductive member 27 connected to the second electronic components 4. The base material 6 has the second conductive member 67 connected to the first conductive member 27 with at least one of the plurality of connection terminals 5 interposed therebetween. At least one of the plurality of external connection electrodes 7 is connected to the second conductive member 67. The wiring layer 12 is in contact with the second electronic components 4.

According to the configuration, the wiring layer 12 is in contact with the second electronic components 4. Accordingly, the space between the second electronic components 4 and the wiring layer 12 can be eliminated, and the height of the radio frequency module 1 can be reduced by an amount corresponding to the elimination. In addition, the wiring layer 12 is provided, and thus a higher degree of freedom in designing the plurality of external connection electrodes 7 can be achieved without necessarily being restricted by the layout of the connection terminals 5.

### (7) Modifications of this Embodiment

Hereinafter, modifications of this embodiment will be described. In the radio frequency module 1 according to each modification below, the same components as those of the radio frequency module 1 according to this embodiment are denoted by the same reference numerals, and description thereof is omitted. This embodiment and any of the following modifications may be combined.

(Modification 1)

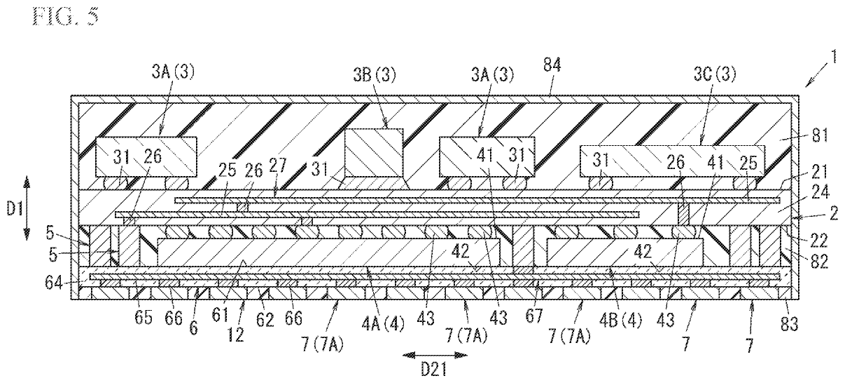

In the embodiment above, at least one of the plurality of external connection electrodes 7 overlaps with the second electronic components 4 (see FIG. 1) in the plan view in the thickness direction D1 of the mounting substrate 2. As illustrated in FIG. 5, in a radio frequency module 1 according to Modification 1, the at least one external connection electrode 7 (that is, the external connection electrode 7 overlapping with the second electronic components 4) is different in a point that the external connection electrode 7 includes a ground electrode 7A. That is, the radio frequency module 1 according to Modification 1 is different from the radio frequency module according to the embodiment above in a point that in the plan view in the thickness direction D1 of the mounting substrate 2, the ground electrode 7A overlaps one of the second electronic components 4.

In Modification 1, heat generated from the second electronic component 4 flows from the sixth main surface 42 of the second electronic components 4 to the wiring layer 12 and is radiated from the ground electrode 7A overlapping with the second electronic component 4. The heat generated from the second electronic component 4 is thus transmitted to the ground electrode 7A through the shortest path and is radiated. This enables the heat generated from the second electronic component 4 to be radiated quickly from the ground electrode 7A. This enables the heat radiation properties of the radio frequency module 1 to be improved. Further, the heat generated from the second electronic components 4 can be prevented from staying inside the mounting substrate 2, and characteristics deterioration due to heat in the radio frequency module 1 can be prevented.

(Modification 2)

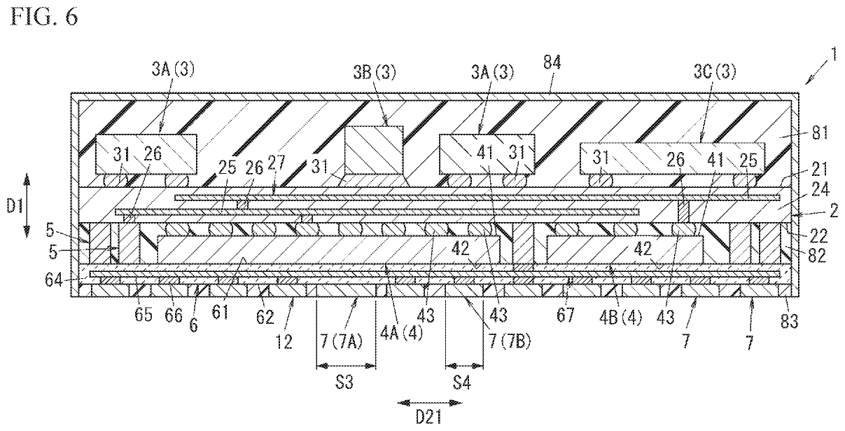

As illustrated in FIG. 6, a radio frequency module 1 according to Modification 2 is different from the radio frequency module according to the embodiment above (see FIG. 1) in a point that in the first direction D21 of the mounting substrate 2, a cross section S3 of the ground electrode 7A of the plurality of external connection electrodes 7 is larger than a cross section S4 of a different electrode (a signal electrode and a power supply electrode) 7B different from the ground electrode 7A.

In Modification 2, the plurality of external connection electrodes 7 include the ground electrode 7A and the different electrode (the signal electrode and the power supply electrode) 7B different from the ground electrode 7A. In Modification 2, the cross section S3 of the ground electrode 7A is larger than the cross section S4 of the different electrode 7B. By making the cross section S3 of the ground electrode 7A larger as described above, the heat generated from the second electronic components 4 can be radiated quickly from the ground electrode 7A.

In addition, among the plurality of external connection electrodes 7, the cross section, in the plan view in the thickness direction D1 of the mounting substrate 2, of one of the external connection electrodes 7 (for example, a ground electrode) that is disposed not to overlap with elements having a problem with the heat radiation properties (for example, a power amplifier and a low noise amplifier) may be made larger than the cross section of some of the external connection electrodes 7 (for example, an electrode other than the ground electrode (a signal electrode and a power supply electrode)) disposed to overlap with elements not having the problem with the heat radiation properties (for example, a filter, a switch, a passive component (for example, a capacitor and an inductor). Heat generated from the element having the problem with the heat radiation properties can be radiated quickly from the external connection electrodes 7.

(Modification 3)

In the embodiment above, the low noise amplifier 14 and the first switch 17 (switch) are exemplified as a specific example of the second electronic components 4. However, apart from this specific example, the second electronic components 4 may be the second switch 18 (switch), the third switch 19 (switch), the controller 20, the power amplifier 11, an integrated passive device (IPD: Integrated Passive Device), or acoustic wave (surface acoustic wave (SAW: Surface Acoustic Wave or BAW: Bulk Acoustic Wave) filters (the transmission filters 121 to 123 and the reception filters 131 to 133). According to Modification 3, in the configuration in which the second electronic components 4 are the second switch 18 (switch), the third switch 19 (switch), the controller 20, the power amplifier 11, the integrated passive device, or the acoustic wave filters, height reduction in the radio frequency module 1 and a higher degree of freedom in designing the external connection electrodes 7 can be achieved.

(Modification 4)

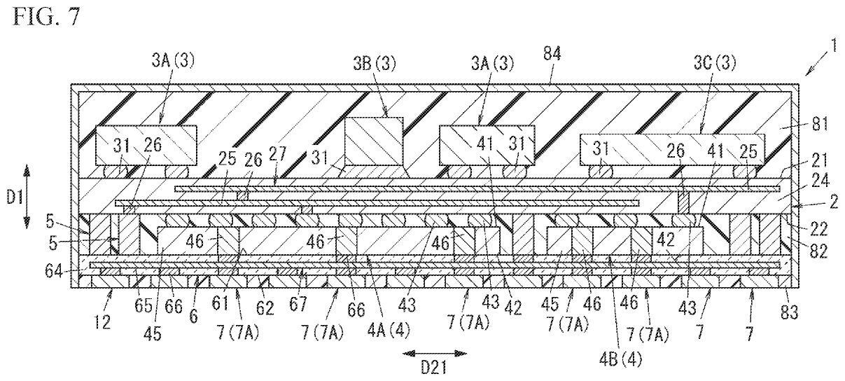

As illustrated in FIG. 7, a radio frequency module 1 according to Modification 4 is different from the radio frequency module according to the embodiment above (see FIG. 1) in a point that the second electronic components 4 have through hole vias 46.

Each second electronic component 4 has a functional unit (not illustrated), a base material (also referred to as a substrate) 45, and the through hole vias 46. The functional unit is a portion including a processing circuit (integrated circuit) for implementing the function of the second electronic component 4. The base material 45 is a member that supports the functional unit and is formed from, for example, an insulative member and into a plate shape. The base material 45 has a fifth main surface 41 and the sixth main surface 42 opposite to each other. The fifth main surface 41 is a main surface on a mounting substrate 2 side of the base material 45 and forms the fifth main surface 41 of the second electronic component 4. The sixth main surface 42 is a main surface on an opposite side of the base material 45 from the mounting substrate 2 side serves as the sixth main surface 42 of the second electronic component 4. The functional unit is disposed on, for example, the main surface on the mounting substrate 2 side of the base material 45 (that is, the fifth main surface 41).

Each through hole via 46 is a member for transmitting heat generated from the corresponding second electronic component 4 (for example, heat generated from the corresponding functional unit) toward the sixth main surface 42 of the base material 45. The through hole via 46 is formed from, for example, a metal (such as copper or a copper alloy). The through hole via 46 has, for example, a columnar (for example, cylindrical) shape.

The through hole via 46 is disposed in the base material 45 to penetrate through a portion between the fifth main surface 41 and the sixth main surface 42 of the base material 45. The through hole via 46 thus penetrates in a thickness direction of the base material 45. An end surface, of the through hole via 46, on a sixth main surface 42 side is in contact with the third main surface 61 of the base material 6 of the wiring layer 12. The one or more through hole vias 46 are disposed in the second electronic component 4. The through hole via 46 may be connected to the ground layer (not illustrated) of the base material 6 with one of the via conductors 66 of the base material 6 interposed therebetween but does not have to be in contact with the ground layer. In the plan view in the thickness direction D1 of the mounting substrate 2, the through hole via 46 overlaps with one of the plurality of external connection electrodes 7 (for example, the ground electrode 7A). The through hole via 46 is connected to the ground electrode 7A overlapping with the through hole via 46 with the via conductor 66 interposed therebetween. The heat generated from the second electronic component 4 can thereby be transmitted quickly from the through hole via 46 to the ground electrode 7A and thus be radiated.

The through hole via 46 does not have to be connected to the ground electrode 7A overlapping with the through hole via 46 with the via conductor 66 interposed therebetween. Since the through hole via 46 simply overlapping with the ground electrode 7A is sufficiently close to the ground electrode 7A, the heat generated from the second electronic component 4 can be transmitted quickly from the through hole via 46 to the ground electrode 7A and thus be radiated.

In Modification 4, the heat generated from the second electronic component 4 is transmitted through the base material 45 to reach the base material 45, flows to the wiring layer 12 through the through hole via 46, and is radiated from the external connection electrode 7 (for example, the ground electrode 7A) overlapping with the through hole via 46. The heat generated from the second electronic component 4 is thereby transmitted quickly to the wiring layer 12 and is radiated from the external connection electrode 7. This enables the heat generated from the second electronic component 4 to be further prevented from staying in the mounting substrate 2 and enables characteristics deterioration due to heat to be further prevented in the radio frequency module 1.

(Modification 5)

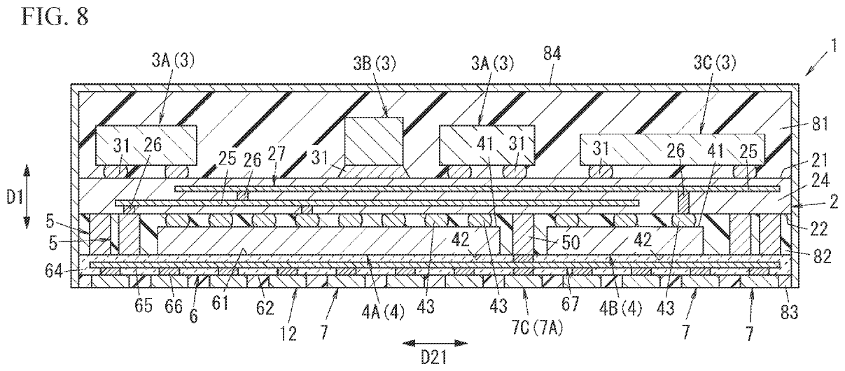

As illustrated in FIG. 8, a radio frequency module 1 according to Modification 5 is different from the radio frequency module according to the embodiment above (see FIG. 1) in a point that radio frequency module 1 includes a conductor member 50 having a ground potential between two adjacent ones of the second electronic components 4.

The conductor member 50 is a member for ensuring isolation (electromagnetic shielding) between the two adjacent second electronic components 4 (for example, 4A and 4B) and maintained at the ground potential. The second electronic component 4A is, for example, the low noise amplifier 14, and the second electronic component 4B is, for example, the first switch 17 (a band selection switch). In Modification 5, the conductor member 50 is thus disposed between the low noise amplifier 14 and the first switch 17 and ensures the isolation between the low noise amplifier 14 and the first switch 17.

The conductor member 50 is formed from, for example, a metal (such as copper or a copper alloy). The conductor member 50 has, for example, a columnar (for example, cylindrical) shape. A plurality of conductor members 50 may be disposed. In this case, the plurality of conductor members 50 are disposed between the two adjacent second electronic components 4 and side by side along the side surfaces facing each other of the two respective second electronic components 4. An end surface on a mounting substrate 2 side of each conductor member 50 is in contact with the second main surface 22 of the mounting substrate 2. An end surface on a wiring layer 12 side of the conductor member 50 is in contact with the third main surface 61 of the base material 6 of the wiring layer 12. The conductor member 50 is thus in contact with the mounting substrate 2 and the base material 6 of the wiring layer 12. The conductor member 50 is connected to at least one of the ground layer of the mounting substrate 2 or the ground layer of the base material 6 of the wiring layer 12 and thereby is maintained at the ground potential.

In the plan view in the thickness direction D1 of the mounting substrate 2, the conductor member 50 overlaps with an external connection electrode 7C (for example, the ground electrode 7A) as one of the plurality of external connection electrodes 7 of the wiring layer 12. The conductor member 50 is electrically connected to the external connection electrode 7C with the corresponding conductive layer 65 and the corresponding via conductor 66 of the base material 6 interposed therebetween. The heat in the mounting substrate 2 can thereby be radiated quickly from the external connection electrode 7C through the conductor member 50. The conductor member 50 overlaps with the external connection electrode 7C and thereby is disposed close to the external connection electrode 7C. Accordingly, even though the conductor member 50 and the external connection electrode 7C are not electrically connected to, the heat in the mounting substrate 2 can be radiated quickly from the external connection electrode 7C through the conductor member 50.

In Modification 5, the isolation between the two adjacent second electronic components 4 (for example, 4A and 4B) can be ensured by using the conductor member 50. The heat in the mounting substrate 2 is radiated from the external connection electrode 7C through the conductor member 50. At this time, the conductor member 50 and the external connection electrode 7C overlap with each other in the plan view in the thickness direction D1 of the mounting substrate 2, and thus the heat in the mounting substrate 2 is transmittable to the external connection electrode 7C in the shortest path. The heat in the mounting substrate 2 is thereby radiated quickly from the external connection electrode 7C. As the result, the heat can be prevented from staying inside the mounting substrate 2, and the characteristics of the radio frequency module 1 can be prevented from being deteriorated.

In Modification 5, as an example of a pair of two adjacent second electronic components 4 isolation between which is ensured by using the conductor member 50, the low noise amplifier 14 and the first switch 17 are exemplified. However, the above-described pair of two adjacent second electronic components 4 may be not only the above-described pair but also a pair of the controller 20 and the low noise amplifier 14, a pair of the controller 20 and the first switch 17, a pair of the second switch 18 and the low noise amplifier 14, or a pair of the second switch 18 and the first switch 17.

The low noise amplifier 14 is an amplifier that amplifies a reception signal with low noise. The first switch 17 is a switch configured to select a filter to be connected to the antenna terminal 101 from among the plurality of filters including the plurality of transmission filters 121 to 123 and the plurality of reception filters 131 to 133. The controller 20 is a controller device for controlling the power amplifier 11. The power amplifier 11 is an amplifier that amplifies a transmission signal. The second switch 18 is a switch configured to perform switching of a transmission filter to be connected to the power amplifier 11 from among the plurality of transmission filters 121 to 123.

The above-described pair of two adjacent second electronic components 4 may also be a pair of an electronic component of a transmission system and an electronic component of a reception system. An electronic component of a transmission system is an electronic component (that is, an electronic component that processes a transmission signal) disposed on a signal path through which the transmission signal flows. An electronic component of a reception system is an electronic component (that is, an electronic component that processes a reception signal) disposed on a signal path through which the reception signal flows.

(Modification 6)

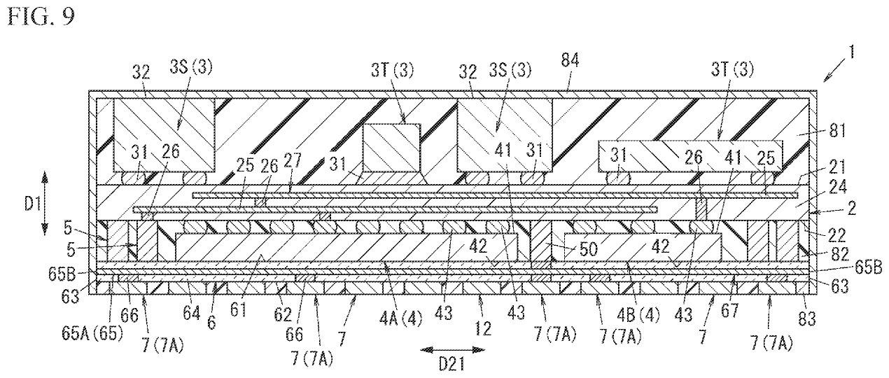

As illustrated in FIG. 9, a radio frequency module 1 according to Modification 6 is different from the radio frequency module according to the embodiment above (see FIG. 1) in a point that the shield layer 84 is in contact with respective top surfaces 32 of specific first electronic components 3S, and is connected to a ground layer 65A of the base material 6 with an outer circumferential surface 63 of the base material 6 interposed therebetween.

In Modification 6, the first resin layer 81 covers an outer circumferential surface of each specific first electronic component 3S but does not cover the top surface (the main surface on an opposite side from the mounting substrate 2 side) 32 of the specific first electronic component 3S. The first electronic components 3S are, for example, the transmission filters 121 to 123 but are not limited to the transmission filters 121 to 123. The first resin layer 81 covers the outer circumferential surfaces and the top surfaces of respective first electronic components 3T of the plurality of first electronic components 3, the first electronic components 3T being other than the specific first electronic components 3S. The top surface of the first resin layer 81 is flush with each top surface 32 of the corresponding first electronic component 3S.

In Modification 6, the plurality of conductive layers 65 of the base material 6 of the wiring layer 12 include the ground layer 65A maintained at the ground potential. Both end portions 65B, in the first direction D21, of the ground layer 65A are exposed on the outer circumferential surface 63 of the base material 6.

In Modification 6, the shield layer 84 covers the top surface and the outer circumferential surface of the first resin layer 81. The shield layer 84 covers each top surface 32 of the corresponding first electronic component 3S. The shield layer 84 covers the top surface 32 of the first electronic component 3S and is thereby in contact with the top surface 32 of the first electronic component 3S. The shield layer 84 also covers the outer circumferential surface of the mounting substrate 2, the outer circumferential surface of the second resin layer 82, the outer circumferential surface 63 of the base material 6, and the outer circumferential surface of the third resin layer 83. At this time, the shield layer 84 is in contact with the outer circumferential surface 63 of the base material 6 and is thereby in contact with the both end portions 65B of the ground layer 65A of the base material 6.

In Modification 6, heat generated from the first electronic component 3S is transmitted from the top surface 32 of the first electronic component 3S to the shield layer 84, transmitted to the outer circumferential surface 63 of the base material 6 through the shield layer 84, and transmitted from the outer circumferential surface 63 to the ground layer 65A. The heat is radiated through the ground layer 65A from the ground electrodes 7A (external connection electrodes 7) connected to the ground layer 65A. The heat generated from the first electronic component 3S can thereby be prevented from flowing to the mounting substrate 2 and can thereby be prevented from staying inside the mounting substrate 2. As the result, characteristics deterioration due to heat in the radio frequency module 1 can be prevented.

(Modification 7)

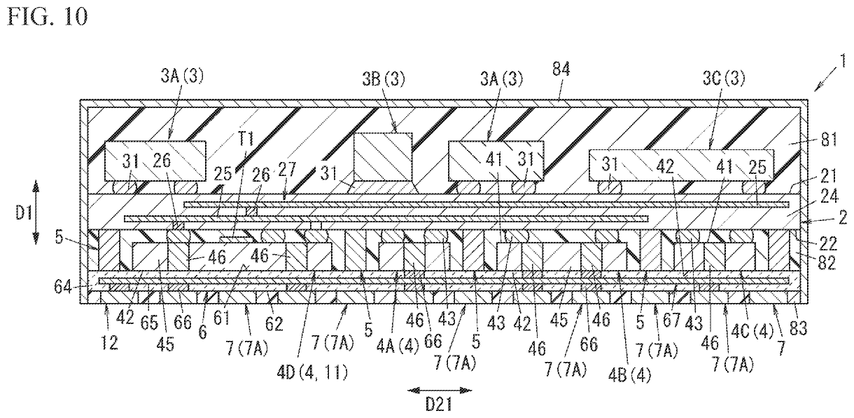

As illustrated in FIG. 10, a radio frequency module 1 according to Modification 7 is different from the radio frequency module according to the embodiment above (see FIG. 1) in a point that the power amplifier 11 is disposed on the second main surface 22 of the mounting substrate 2, instead of the first main surface 21 of the mounting substrate 2. In Modification 7, the case where the power amplifier 11 is disposed on the second main surface 22 of Embodiment 2 is exemplified; however, instead of the power amplifier 11, a low noise amplifier may be disposed on the second main surface 22 of the mounting substrate 2.

In Modification 7, a second electronic component 4D of the plurality of second electronic components 4 is the power amplifier 11. The power amplifier 11 is disposed on the second main surface 22 of the mounting substrate 2. In more detail, the power amplifier 11 is electrically connected to the second main surface 22 of the mounting substrate 2 with the bumps 43 interposed therebetween. On the fifth main surface 41 on a mounting substrate 2 side of the power amplifier 11, a transistor T1 is disposed, the transistor T1 forming a functional unit (for example, a transistor (amplification device) used at the last processing stage in a plurality of processing stages of the functional unit). The sixth main surface 42 on an opposite side of the power amplifier 11 from the mounting substrate 2 side is not covered with the second resin layer 82 and is in contact with the third main surface 61 on the mounting substrate 2 side of the base material 6 of the wiring layer 12. The base material 6 is thus in contact with the sixth main surface 42 on the opposite side of the power amplifier 11 from the mounting substrate 2 side.

In Modification 7, like Modification 4, the power amplifier 11 includes the through hole vias 46. Each through hole via 46 penetrates through the base material 45 in the thickness direction (thickness direction D1) and is in contact with the third main surface 61 of the base material 6. In the plan view in the thickness direction D1 of the mounting substrate 2, at least one of the through hole vias 46 overlaps with one of the plurality of external connection electrodes 7 (for example, the ground electrode 7A). The through hole via 46 may be electrically connected or does not have to be connected to the ground electrode 7A overlapping with the through hole via 46 with a corresponding one of the via conductors 66 or the like interposed therebetween.

In Modification 7, heat generated from the power amplifier 11 (for example, heat generated from the transistor T1) is transmitted to the base material 45 to reach the through hole vias 46. The heat flows to the wiring layer 12 through the through hole vias 46 and is radiated from the external connection electrode 7 (for example, the ground electrode 7A) overlapping with the corresponding through hole via 46. The heat generated from the transistor T1 is thereby transmitted to the wiring layer 12 through the through hole vias 46, transmitted quickly to the wiring layer 12, and radiated from the external connection electrode 7. This enables the heat generated from the transistor T1 to be further prevented from staying inside the mounting substrate 2 and enables characteristics deterioration due to heat to be further prevented in the radio frequency module 1.

### Aspects

This specification discloses the following aspects.

A radio frequency module (1) according to a first aspect includes a mounting substrate (2), a first electronic component (3), a second electronic component (4), a plurality of connection terminals (5), and a wiring layer (12). The mounting substrate (2) has a first main surface (21) and a second main surface (22) that are opposite to each other. The first electronic component (3) is disposed on the first main surface (21) of the mounting substrate (2). The second electronic component (4) is disposed on the second main surface (22) of the mounting substrate (2). The plurality of connection terminals (5) are disposed on the second main surface (22) of the mounting substrate (2) and are connected to the mounting substrate (2). The wiring layer (12) faces the second main surface (22) of the mounting substrate (2) with the second electronic component (4) interposed therebetween and is connected to the plurality of connection terminals (5). The second electronic component (4) is located between the mounting substrate (2) and the wiring layer (12). The wiring layer (12) has a base material (6) and a plurality of external connection electrodes (7). The base material (6) has a third main surface (61) and a fourth main surface (62) that are opposite to each other and is connected to the plurality of connection terminals (5) with the third main surface (61) interposed therebetween. The plurality of external connection electrodes (7) are disposed on the fourth main surface (62) of the base material (6). The mounting substrate (2) has a first conductive member (27) connected to the second electronic component (4). The base material (6) has a second conductive member (67) connected to the first conductive member (27) with at least one of the plurality of connection terminals (5) interposed therebetween. At least one of the plurality of external connection electrodes (7) is connected to the second conductive member (67). The wiring layer (12) is in contact with the second electronic component (4).

According to the configuration, the wiring layer (12) is in contact with the second electronic component (4). Accordingly, a space between the second electronic component (4) and the wiring layer (12) can be eliminated, and the height of the radio frequency module (1) can be reduced by an amount corresponding to the elimination. In addition, the wiring layer (12) is provided, and thus a higher degree of freedom in designing the plurality of external connection electrodes (7) can be achieved without necessarily being restricted by the layout of the connection terminals (5).

In the first aspect, in the radio frequency module (1) according to a second aspect, the base material (6) is in contact with the second electronic component (4).

In the first or second aspect, in the radio frequency module (1) according to a third aspect, in a plan view in a thickness direction (D1) of the mounting substrate (2), at least one of the plurality of external connection electrodes (7) overlaps with the second electronic component (4).

According to the configuration, a distance between the second electronic component (4) or the at least one external connection electrode (7) can be made shorter. A heat radiation path from the at least one external connection electrode (7) to the second electronic component (4) can thereby be made shorter, and the heat radiation properties of the radio frequency module (1) can be improved. As the result, heat generated from the second electronic component (4) can be prevented from staying inside the mounting substrate (2) and the characteristics deterioration due to heat in the radio frequency module (1) can be prevented.

In the third aspect, in the radio frequency module (1) according to a fourth aspect, the at least one external connection electrode (7) includes a ground electrode (7A).

According to the configuration, the heat generated from the second electronic component (4) is radiated from the ground electrode (7A), and thus the heat generated from the second electronic component (4) can be radiated quickly.

In any one of the first to third aspects, in the radio frequency module (1) according to a fifth aspect, in the plan view in the thickness direction (D1) of the mounting substrate (2), the plurality of external connection electrodes (7) include an external connection electrode (7) that overlaps with one of the plurality of connection terminals (5).

In the fourth aspect, in the radio frequency module (1) according to a sixth aspect, the plurality of external connection electrodes (7) include the ground electrode (7A) and a different electrode (7B) different from the ground electrode (7A). In the plan view in the thickness direction (D1) of the mounting substrate (2), a cross section (S3) of the ground electrode (7A) is larger than a cross section (S4) of the different electrode (7B).

According to the configuration, the cross section (S3) of the ground electrode (7A) can be increased. The heat generated from the second electronic component (4) can thereby be radiated quickly from the ground electrode (7A).

In any one of the first to sixth aspects, in the radio frequency module (1) according to a seventh aspect, the base material (6) is a first base material (6). The second electronic component (4) has a second base material (45) and a through hole via (46). The second base material (45) has a fifth main surface (41) and a sixth main surface (42) that are opposite to each other, the fifth main surface (41) being located on a mounting substrate (2) side, the sixth main surface (42) being located on an opposite side from the mounting substrate (2) side. The through hole via (46) penetrates through a portion between the fifth main surface (41) and the sixth main surface (42).

According to the configuration, the through hole via (46) enables the heat generated from the second electronic component (4) to be transmitted to the wiring layer (12) quickly. The heat generated from the second electronic component (4) can thereby be prevented from being transmitted to the mounting substrate (2) side.

In the seventh aspect, in the radio frequency module (1) according to an eighth aspect, in the plan view in the thickness direction (D1) of the mounting substrate (2), the through hole via (46) overlaps with at least one external connection electrode (7) of the plurality of external connection electrodes (7).

According to the configuration, a distance between the through hole via (46) and the one external connection electrode (7) can be made shorter. The heat transmitted from the second electronic component (4) to the base material (6) through the through hole via (46) can thereby be radiated quickly from the one external connection electrode (7).

In the eighth aspect, in the radio frequency module (1) according to a ninth aspect, the external connection electrode (7) overlapping with the through hole via (46) is the ground electrode (7A).

According to the configuration, the heat transmitted from the second electronic component (4) to the wiring layer (12) through the through hole via (46) can be radiated quickly from the ground electrode (7A).

In any one of the seventh to ninth aspects, in the radio frequency module (1) according to a 10th aspect, the through hole via (46) is in contact with the wiring layer (12).

In any one of the seventh to 10th aspects, in the radio frequency module (1) according to an 11th aspect, the second electronic component (4) is a power amplifier or a low noise amplifier.

In any one of the seventh to 11th aspects, in the radio frequency module (1) according to a 12th aspect, the second electronic component (4) further includes an amplification device (a transistor T1) disposed on the fifth main surface (41) of the second base material (45).

In any one of the first to ninth aspects, the radio frequency module (1) according to a 13th aspect includes a plurality of the second electronic components (4). The wiring layer (12) is in contact with all of the plurality of second electronic components (4).

According to the configuration, for the contact with all of the plurality of second electronic components (4), a thickness of each of the plurality of second electronic components (4) is required to be made equal to a thickness of a thinnest one of the second electronic components (4). Accordingly, further height reduction in the radio frequency module (1) can be achieved.

In the 13th aspect, the radio frequency module (1) according to a 14th aspect further includes a conductor member (50) having a ground potential. The conductor member (50) is disposed between two adjacent second electronic components (4) of the plurality of second electronic components (4). The conductor member (50) is in contact with the mounting substrate (2) and the wiring layer (12). The plurality of external connection electrodes (7) include the ground electrode (7A). In the plan view in the thickness direction (D1) of the mounting substrate (2), the conductor member (50) overlaps with the ground electrode (7A).

According to the configuration, the conductor member (50) enables isolation (electromagnetic shielding) between the two second electronic components (4) to be ensured. Disposing the conductor member (50) between the two second electronic component (4) means disposing the conductor member (50) between the mounting substrate (2) and the wiring layer (12). Disposing the conductor member (50) between the mounting substrate (2) and the wiring layer (12) causes the conductor member (50) to lead to easy transmission of the heat in the mounting substrate (2) to the wiring layer (12) and easy radiation of the heat in the mounting substrate (2) from the external connection electrodes (7). The heat radiation properties of the radio frequency module (1) can thereby be improved.

According to the configuration of the radio frequency module (1) according to the 14th aspect, an effect of the isolation of the conductor member (50) can be enhanced. The heat in the mounting substrate (2) can be transmitted quickly from the mounting substrate (2) to the wiring layer (12) through the conductor member (50).

According to the configuration of the radio frequency module (1) according to the 14th aspect, a distance between the conductor member (50) and the ground electrode (7A) can be made shorter. The heat in the mounting substrate (2) can thereby be radiated quickly from the ground electrode (7A) through the conductor member (50) and the wiring layer (12).

In the 14th aspect, in the radio frequency module (1) according to a 15th aspect, the conductor member (50) is electrically connected to the ground electrode (7A) with the second conductive member (67) of the base material (6) of the wiring layer (12) interposed therebetween.

In any one of the first to 15th aspects, the radio frequency module (1) according to a 16th aspect further includes a first resin layer (81), a second resin layer (82), a third resin layer (83), and a shield layer (84). The first resin layer (81) is disposed on the first main surface (21) of the mounting substrate (2) to cover the first electronic component (3). The second resin layer (82) is disposed between the mounting substrate (2) and the wiring layer (12). The third resin layer (83) is disposed on the fourth main surface (62) of the base material (6) to cover an outer circumferential surface of each of the plurality of external connection electrodes (7). The shield layer (84) covers the first resin layer (81), an outer circumferential surface of the mounting substrate (2), an outer circumferential surface of the second resin layer (82), an outer circumferential surface of the wiring layer (12), and an outer circumferential surface of the third resin layer (83). The shield layer (84) is in contact with at least part of an outer circumferential surface of a ground layer of the base material (6) of the wiring layer (12).

In the 16th aspect, in the radio frequency module (1) according to a 17th aspect, the shield layer (84) is in contact with a surface (32) on an opposite side of the first electronic component (3) from a mounting substrate (2) side. The plurality of external connection electrodes (7) include the ground electrode (7A). The ground electrode (7A) is connected to a ground layer (65A) of the base material (6) with a via conductor (66) in the wiring layer (12) interposed therebetween.

In any one of the first to 17th aspects, in the radio frequency module (1) according to an 18th aspect, in the plan view in the thickness direction (D1) of the mounting substrate (2), a cross section (S1) of each of the plurality of connection terminals (5) is different from a cross section (S2) of one of the plurality of external connection electrodes (7).

According to the configuration, the cross section (S2) of the external connection electrode (7) can be made different from the cross section (S1) of the connection terminal (5).

In any one of the first to 18th aspects, in the radio frequency module (1) according to a 19th aspect, the base material (6) is thinner than the mounting substrate (2).

According to the configuration, further height reduction in the radio frequency module (1) can be achieved.

A communication apparatus (9) according to a 20th aspect includes the radio frequency module (1) according to any one of the first to 19th aspects and a signal processing circuit (92) that processes a signal that passes through the radio frequency module (1).

According to the configuration, the communication apparatus (9) including the radio frequency module (1) having the effects above can be provided.

### REFERENCE SIGNS LIST

1 radio frequency module
9 communication apparatus
10 external connection terminal
12 wiring layer
50 conductor member
101 antenna terminal
102 signal input terminal
103 signal output terminal
104 input terminal
11 power amplifier
121, 122, 123 transmission filter (surface acoustic wave filter)
131, 132, 133 reception filter (surface acoustic wave filter)
14 low noise amplifier
15 output matching circuit
16 input matching circuit
17 first switch
171 common terminal
172, 173, 174 selection terminal
18 second switch
181 common terminal
182, 183, 184 selection terminal
19 third switch
191 common terminal
192, 193, 194 selection terminal
20 controller
2 mounting substrate
21 first main surface
22 second main surface
24 dielectric layer
25 conductive layer
26 via conductor
27 first conductive member
3, 3A, 3B, 3C, 3S, 3T first electronic component
31 bump
32 top surface
4, 4A, 4B, 4D second electronic component
41 fifth main surface
42 sixth main surface
43 bump
45 base material
46 through hole via
5 connection terminal
6 base material
61 third main surface
62 fourth main surface
63 outer circumferential surface
64 dielectric layer
65 conductive layer
65A ground layer
65B both end portions
66 via conductor
67 second conductive member
7, 7C external connection electrode
7A ground electrode
7B different electrode
81 first resin layer
82 second resin layer
83 third resin layer
84 shield layer
9 communication apparatus
91 antenna
92 signal processing circuit
93 RF signal processing circuit
94 baseband signal processing circuit
A1 area
S1, S2, S3, S4 cross section
D1 thickness direction
D21 first direction
D22 second direction
T1 transistor (amplification device)

1. A radio frequency module comprising:
a mounting substrate having a first main surface and a second main surface that are opposite to each other;
a first electronic component on the first main surface of the mounting substrate;
a second electronic component on the second main surface of the mounting substrate;
a plurality of connection terminals on the second main surface of the mounting substrate and connected to the mounting substrate; and
a wiring layer that faces the second main surface of the mounting substrate with the second electronic component interposed between the wiring layer and the second main surface, and that is connected to the plurality of connection terminals,
wherein the second electronic component is located between the mounting substrate and the wiring layer,
wherein the wiring layer comprises:
a base material that has a third main surface and a fourth main surface, and that is connected to the plurality of connection terminals with the third main surface interposed between the base material and the plurality of connection terminals, the third main surface and the fourth main surface being opposite to each other, and
a plurality of external connection electrodes on the fourth main surface of the base material,
wherein the mounting substrate comprises a first conductor connected to the second electronic component,
wherein the base material comprises a second conductor connected to the first conductor with at least one of the plurality of connection terminals interposed between the second conductor and the first conductor,
wherein at least one of the plurality of external connection electrodes is connected to the second conductor, and
wherein the wiring layer is in contact with the second electronic component.

2. The radio frequency module according to claim 1, wherein the base material is in contact with the second electronic component.

3. The radio frequency module according to claim 1, wherein in a plan view in a thickness direction of the mounting substrate, at least one of the plurality of external connection electrodes overlaps the second electronic component.

4. The radio frequency module according to claim 3, wherein the at least one external connection electrode comprises a ground electrode.

5. The radio frequency module according to claim 1, wherein in the plan view in the thickness direction of the mounting substrate, the plurality of external connection electrodes comprises an external connection electrode that overlaps one of the plurality of connection terminals.

6. The radio frequency module according to claim 4,
wherein the plurality of external connection electrodes comprises the ground electrode and a different electrode that is different from the ground electrode, and
wherein in the plan view in the thickness direction of the mounting substrate, a cross section of the ground electrode is larger than a cross section of the different electrode.

7. The radio frequency module according to claim 1,
wherein the base material is a first base material, and
wherein the second electronic component comprises:
a second base material that has a fifth main surface and a sixth main surface that are opposite to each other, the fifth main surface being on a mounting substrate side, the sixth main surface being on an opposite side from the mounting substrate side, and
a through hole via that penetrates through a portion between the fifth main surface and the sixth main surface.

8. The radio frequency module according to claim 7, wherein in the plan view in the thickness direction of the mounting substrate, the through hole via overlaps at least one of the plurality of external connection electrodes.

9. The radio frequency module according to claim 8, wherein the external connection electrode overlapping the through hole via is the ground electrode.

10. The radio frequency module according to claim 7, wherein the through hole via is in contact with the wiring layer.

11. The radio frequency module according to claim 7, wherein the second electronic component is a power amplifier or a low noise amplifier.

12. The radio frequency module according to claim 7, wherein the second electronic component further comprises an amplifier on the fifth main surface of the second base material.

13. The radio frequency module according to claim 1, comprising:
a plurality of the second electronic components,
wherein the wiring layer is in contact with all of the plurality of second electronic components.

14. The radio frequency module according to claim 13, further comprising:
a conductor having a ground potential that is between two adjacent second electronic components of the plurality of second electronic components,
wherein the conductor is in contact with the mounting substrate and the wiring layer,
wherein the plurality of external connection electrodes comprises the ground electrode, and
wherein in the plan view in the thickness direction of the mounting substrate, the conductor overlaps the ground electrode.

15. The radio frequency module according to claim 14, wherein the conductor is electrically connected to the ground electrode with the second conductor of the base material of the wiring layer interposed between the conductor and the ground electrode.

16. The radio frequency module according to claim 1, further comprising:
a first resin layer on the first main surface of the mounting substrate that covers the first electronic component;
a second resin layer between the mounting substrate and the wiring layer; and
a shield layer that covers the first resin layer, an outer circumferential surface of the mounting substrate, an outer circumferential surface of the second resin layer, and an outer circumferential surface of the wiring layer,
wherein the shield layer is in contact with at least part of an outer circumferential surface of a ground layer of the base material of the wiring layer.

17. The radio frequency module according to claim 16,
wherein the shield layer is in contact with a surface on an opposite side of the first electronic component from a mounting substrate side,
wherein the plurality of external connection electrodes comprises the ground electrode, and
wherein the ground electrode is connected to a ground layer of the base material with a via conductor in the wiring layer interposed between the ground electrode and the ground layer.

18. The radio frequency module according to claim 1, wherein in the plan view in the thickness direction of the mounting substrate, a cross section of each of the plurality of connection terminals is different from a cross section of one of the plurality of external connection electrodes.

19. The radio frequency module according to claim 1, wherein the base material is thinner than the mounting substrate.

20. A communication apparatus comprising:
the radio frequency module according to claim 1; and
a signal processing circuit configured to process a signal that passes through the radio frequency module.
